(19) United States
(12) Patent Application Publication
(10) Pub. No.: US 2010/0273331 A1
(43) Pub. Date: Oct. 28, 2010

(54) METHOD OF FABRICATING A NANO/MICRO STRUCTURE

(75) Inventors: Chia-Hua Chan, Keelung City (TW); Jen-Inn Chyi, Taoyuan County (TW); Chang-Chi Pan, Pingtung County (TW); Chii-Chang Chen, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NATIONAL CENTRAL UNIVERSITY, Taoyuan (TW)

(21) Appl. No.: 12/831,265

(22) Filed: Jul. 7, 2010

Related U.S. Application Data
(63) Continuation-in-part of application No. 11/309,168, filed on Jul. 5, 2006.

(51) Int. Cl. H01L 21/302

(52) U.S. Cl. 438/694; 257/E21.214; 438/29

(57) ABSTRACT

A method of fabricating a nano/micro structure comprising the following steps is provided. First, a film is provided and then a mixed material comprising a plurality of ball-shape particles and a filler among the ball-shape particles is formed on the film. Next, the ball-shape particles are removed by the etching process, the solvent extraction process or the like, such that a plurality of concaves is formed on the surface of the filler, which serves as a nano/micro structure of the film.

### CROSS-REFERENCE TO RELATED APPLICATION

This application is a continuation-in-part of a prior application Ser. No. 11/309,168, filed on Jul. 5, 2006, now pending. The entirety of the above-mentioned patent application is hereby incorporated by reference herein and made a part of this specification.

### BACKGROUND OF THE INVENTION

1. Field of the Invention

The present invention generally relates to a method of fabricating a nano/micro structure, and more particularly, to a method of fabricating one or more roughness layer in a light emitting diode for enhancing the extraction efficiency thereof.

2. Description of Related Art

The LED is a semiconductor element that has been widely used in light emitting devices. Generally, the LED chip is made up of III-V group compound semiconductors, such as GaP, GaAs, GaN and so on. The light emitting principle is to convert electrical energy into light, that is, a current is applied to the compound semiconductor, and by combining electrons with holes, the energy is converted into light so as to achieve the light emitting effect. Since LEDs have the advantages of rapid response speed (generally within about nano-second), preferable monochromaticity, small volume, low electrical power consumption, low pollution (free of mercury), high reliability, applicability for mass production processes, etc., they are widely used, such as in traffic light signals, display panels with large volumes, and display interfaces of various portable electronic devices, etc.

Basically, an LED comprises a P-type III-V group compound, an N-type III-V group compound, and a light emitting layer sandwiched there between, and is fabricated by means of epitaxy. The light emitting efficiency of the LED is the product of the internal quantum efficiency and the extraction efficiency thereof, which is called collectively as the external quantum efficiency. Since the LED has achieved the theoretical limit of the internal quantum efficiency, therefore, how to enhance the extraction efficiency of the LED is an important issue in this technology.

The light extraction efficiency of the LED is changed according to the geometry, the absorptivity, the scattering characteristics of the materials of the LED device, and the difference between the refraction index of the package material and that of the LED. To enhance the light extraction efficiency of the LED, one conventional technique is to roughen the surface of the LED substrate. The process includes roughening a surface of the LED substrate by etching to prevent the occurrence of total internal reflection of light inside the LED, which reduces the overall light utilization.

However, the surface roughness achieved by the etching process has the following disadvantages:

(1) Some substrates, such as sapphire substrates, are difficult to be etched and take longer etching processing time with effects on the productivity.

(2) Generally speaking, the photolithography and semiconductor process used for etching the substrate require expensive semiconductor equipments, and may lead to an increase on the fabrication cost of the LED.

### SUMMARY OF THE INVENTION

Accordingly, one purpose of the present invention is to provide a method of fabricating a nano/micro structure having highly-ordered concaves in LEDs.

As embodied and broadly described herein, the present invention is directed to a method of fabricating a nano/micro structure. First, a substrate is provided and then a plurality of ball-shape particles is formed on the substrate.

According to an embodiment of the present invention, wherein the substrate is a film, a silicon substrate or a sapphire substrate.

According to an embodiment of the present invention, wherein the ball-shape particles are mixed within a filler to form a mixed material.

According to an embodiment of the present invention, wherein a material of the filler comprises an inorganic material. Furthermore, the inorganic material comprises metal alkoxides, metal oxide precursor or a plurality of metal particles.

According to an embodiment of the present invention, after the ball-shape particles are formed on the substrate, the ball-shape particles are further removed by an etching process, a thermal treatment process, a solvent extraction process or the like.

According to an embodiment of the present invention, the mixed material is formed on the surface of the substrate by spinning coating, dip coating or natural drying.

According to an embodiment of the present invention, a material of the ball-shape particles comprises polymer, metal or metal oxide.

According to an embodiment of the present invention, the ball-shape particles comprise a plurality of micro-scaled particles, a plurality of nano-scaled particles, or a mixture of the micro-scaled particles and the nano-scaled particles.

According to an embodiment of the present invention, before the step of forming the ball-shape particles on the substrate, further comprises a step of depositing a monolayer on the substrate, wherein a material of the monolayer is SiO2 or AlGaN, Al2O3, ZnO, AZO, ITO, Si, GaN and FTO. In addition, after the step of forming the ball-shape particles on the substrate, further comprises a step of etching the ball-shape particles, the monolayer and the substrate by using the ball-shape particles as a mask to form a plurality of concaves on a surface of the substrate or the monolayer.

According to an embodiment of the present invention, after the step of forming the ball-shape particles on the substrate, further comprises a step of etching the ball-shape particles and the substrate by using the ball-shape particles as a mask to form a plurality of concaves on a surface of the substrate.

In summary, the fabrication of the nano/micro structure may be applied into an LED device to be roughed, such that the extraction efficiency of the LED device is enhanced. Compared with the etching process, the fabrication method of the present invention may reduce the fabrication time and cost effectively, thus increasing the productivity.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1C are schematic, cross-sectional diagrams illustrating the process flow for fabricating a nano/micro structure according to a first embodiment of the present invention.

FIG. 2 is a picture of a nano/micro structure formed on a substrate according to the above-mentioned processes captured by an electron-microscope.

FIG. 3 is a cross-sectional view showing an LED device with the nano/micro structure of the first embodiment of the present invention.

FIG. 4 is a cross-sectional view showing an LED having two roughness layers according to another preferred embodiment of the present invention.

FIG. 5 is a cross-sectional view showing an LED having three roughness layers according to another preferred embodiment of the present invention.

FIG. 6 is a diagram illustrating a relationship of wavelength and RT-PL intensity measured from the standard 400 nm LED structure and the 400 nm LED structure on the substrate having the nano/micro structure according to an embodiment of the present invention.

FIG. 7 is a diagram illustrating a relationship of injection current and EL integrated intensity measured from the standard 400 nm LED structure and the 400 nm LED structure on the substrate having the nano/micro structure according to an embodiment of the present invention.

FIGS. 8A to 8C are schematic, cross-sectional diagrams illustrating the process flow for fabricating a nano/micro structure according to a second embodiment of the present invention.

FIGS. 9A to 9D are schematic, cross-sectional diagrams illustrating the process flow for fabricating a nano/micro structure according to a third embodiment of the present invention.

FIGS. 10A and 10B are schematic, cross-sectional diagrams illustrating the process flow for fabricating a nano/micro structure according to a fourth embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

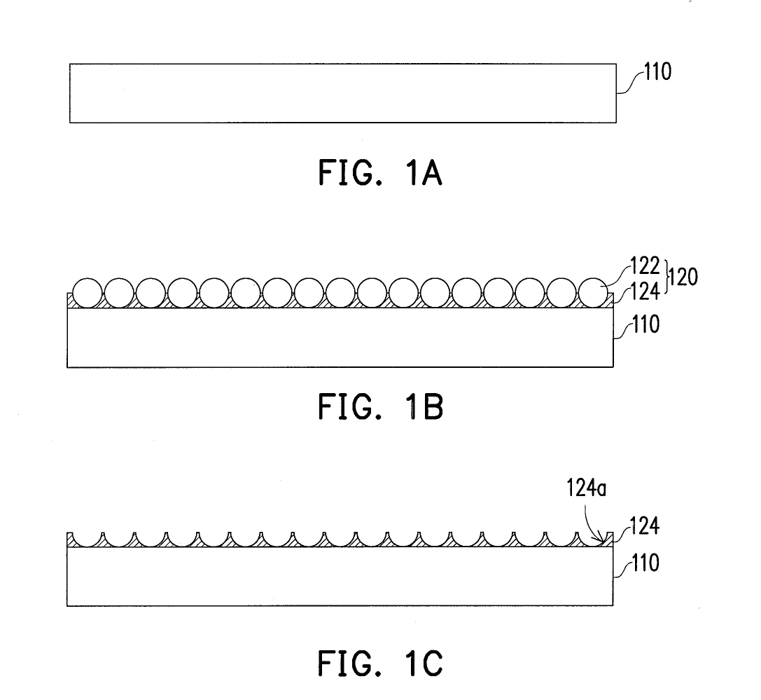

FIGS. 1A to 1C are schematic, cross-sectional diagrams illustrating the process flow for fabricating a nano/micro structure according to a first embodiment of the present invention. First, referring to FIG. 1A, a substrate 110 is provided. In one embodiment of the present invention, the substrate 110 may be the LED substrate, such as the sapphire substrate, or one of the films of the LED device, such as the N-type doped semiconductor layer, the P-type doped semiconductor layer or the transparent conductive layer to be roughed.

Then, please refer to FIG. 1B, a mixed material 120 is formed on the substrate 110, and the mixed material 120 comprises a plurality of ball-shape particles 122 and a filler 124 among the ball-shape particles 122. In this embodiment, the ball-shape particles 122 and the filler 124 in liquid phase are mixed together in advance, and then a layer of the filler 124 and the ball-shape particles 122 distributed therein is coated onto the substrate 110 by spinning coating. Basically, the mixed material 120 having the ball-shape particles 122 has formed a nano/micro structure with a convex surface. However, if a nano/micro structure with a concave surface is desired, the user may need to proceed with the following step. By controlling a rotation speed of the spinning coating process, the ball-shape particles 122 may be periodically arranged in a mono-layer on the substrate 110. Besides, the ball-shape particles 122 may be arranged in two or more layers according to the concentration of the mixed solution coated on the substrate 110 and/or the rotation speed; however the number of the layers is not limited in the present invention. Except spinning coating, the mixed material 120 can be formed on the substrate 110 by dip coating, natural drying or other suitable method. The ball-shape particles 122 may be in contact with the neighboring ball-shape particles, or otherwise separated from each other as shown in FIG. 1B. In one embodiment of the present invention, the ball-shape particles 122 may comprise a plurality of micro-scaled particles, a plurality of nano-scaled particles, or a mixture of the micro-scaled particles and the nano-scaled particles. The ball-shape particles 122 may be made of polymer, metal or metal oxide. For example, the material of the polymer comprises polymethylmethacrylate (PMMA), polystyrene (PS) and so on; the material of the metal comprises gold, silver, copper, Ni, Ti, Al and the like; the material of the metal oxide comprises silicon dioxide, titanium dioxide and the like. Besides, a material of the filler 124 comprises an inorganic material, and the inorganic material may be metal alkoxides, metal oxide precursor or a plurality of metal particles, but is not limited.

Finally, please refer to FIG. 1C, the ball-shape particles 122 are removed, such that a plurality of highly-ordered concaves 124a is formed on the surface of the filler 124, which serves as a nano/micro structure on the substrate 110. The size of the concaves 124a may be changed according to the diameter of the ball-shape particles 122. Besides, according to an embodiment of the present invention, the ball-shape particles 122 can be removed by the etching process, the solvent extraction process, the thermal treatment process or other suitable process. Thus far, the nano/micro structure on the substrate 110 is formed according to the above processes.

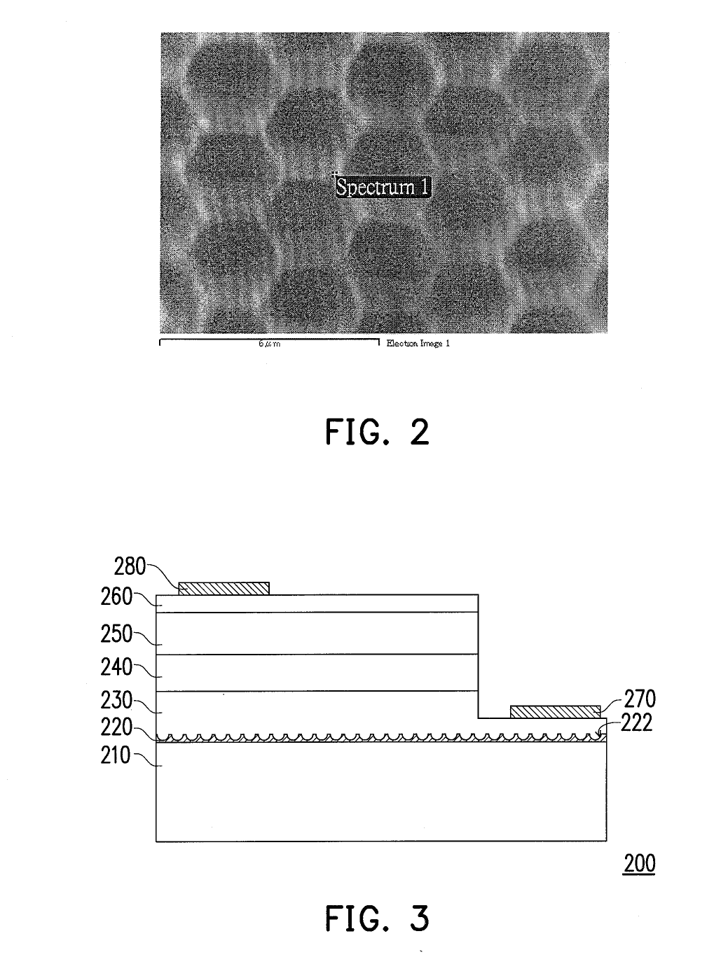

FIG. 2 is a picture of a nano/micro structure formed on a substrate according to the above-mentioned processes captured by an electron-microscope. The fabrication process of the nano/micro structure on the substrate comprises the following steps. First, a mixture of the micro-scaled styrene particles and the solution having aluminium particles is coated on the sapphire substrate. Then, the micro-scaled styrene particles are removed, such that a nano/micro structure, which is comprised of aluminium oxide and has a plurality of micro-scaled concaves, is formed on the sapphire substrate.

The fabrication of the nano/micro structure may be applied to any kinds of the light emitting devices for enhancing the light emitting efficiency thereof. In the present invention, the fabrication of the nano/micro structure is applied to one or more of the substrates of the LED device in order to avoid the occurrence of the total internal reflection, wherein the substrates may be sapphire or films such as a semiconductor layer, a light emitting layer, a doped semiconductor layer, or a transparent conductive layer of the LED device. The LED devices having the nano/micro structure on one or more of the substrates are illustrated as follows.

FIG. 3 is a cross-sectional view showing an LED device with the nano/micro structure of the first embodiment applied therein of the present invention. Referring to FIG. 3, the LED 200 mainly comprises a substrate 210, a first roughness layer 220, a first type doped semiconductor layer 230, a light emitting layer 240, a second type doped semiconductor layer 250, a transparent conductive layer 260, a first electrode 270 and a second electrode 280. The first roughness layer 220 having a plurality of micro-scaled or nano-scaled concaves 222 is adapted to enhance the extraction efficiency of the LED 200 and is formed on the substrate 210 according to the above-mentioned processes. Furthermore, a material of the first roughness layer 220 depends on that of the precursor, and therefore the material of the first roughness layer 220 may be the same or different from that of the substrate 210. Then, an active layer constructed by the first type doped semiconductor layer 230, the light emitting layer 240 and the second type doped semiconductor layer 250 is formed, for example but not limited to, by performing a series of epitaxy processes sequentially on the first roughness layer 220. In this embodiment, the first type doped semiconductor layer 230 is an N-type doped semiconductor layer, and the second type doped semiconductor layer 250 is a P-type N-type doped semiconductor layer.

Moreover, in the succeeding process, a portion of the first type doped semiconductor layer 230, a portion of the light emitting layer 240 and a portion of the second type doped semiconductor layer 250 are removed, for example but not limited to, by etching or by another method, to form an isolated island structure (MESA). Then, the transparent conductive layer 260 is formed on the second type doped semiconductor layer 250. Finally, the first electrode 270 is formed on the exposed first type doped semiconductor layer 230, and the second electrode 280 electrically isolated from the first electrode 270 is formed on the transparent conductive layer 260. Since the surface of the substrate 210 is roughed by the fabrication of the first roughness layer 220, which does not require the etching process, therefore, the fabrication time and cost of the LED device can be reduced.

The substrate 210 may be a glass substrate, a silicon substrate, a sapphire substrate or the like. A material of the first roughness layer 220 comprises an inorganic material, such as metal alkoxides, metal oxide precursor or a plurality of metal particles. A material of the first type doped semiconductor layer 230 and the second type doped semiconductor layer 250 comprises a III-V group compound of semiconductor material, such as a gallium nitride (GaN), a gallium phosphide (GaP) or a gallium phosphide arsenide (GaAsP). The light emitting layer 240 may comprise a single or a multi quantum well structure, to enhance the light emitting efficiency. Besides, a material of the transparent conductive layer 260 preferably comprises an indium tin oxide (ITO), but also may comprise, for example but not limited to, such as indium tin oxide, cadmium tin oxide, ZnO:Al, ZnGa₂O4, SnO₂:Sb, Ga₂O₃:Sn, AgInO₂:Sn, In₂O₃:Zn, NiO, MnO, FeO, Fe₂O₃, CoO, CrO, Cr₂O₃, CrO₂, CuO, SnO, Ag₂O, CuAlO₂, SrCu₂O₂, LaMnO₃, PdO or the like. The first electrode 270 can be made of a metallic alloy including Ti/Al, Ti/Al/Ti/Au, Ti/Al/Pt/Au, Ti/Al/Ni/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au, Cr/Al/Ni/Au, Pd/Al/Ti/Au, Pd/Al/Pt/Au, Pd/Al/Ni/Au, Pd/Al/Pd/Au, Pd/Al/Cr/Au, Pd/Al/Co/Au, Nd/Al/Pt/Au, Nd/Al/Ti/Au, Nd/Al/Ni/Au, Nd/Al/Cr/Au, Nd/Al/Co/A, Hf/Al/Ti/Au, Hf/Al/t/Au, Hf/Al/Ni/Au, Hf/Al/Pd/Au, Hf/Al/Cr/Au, Hf/Al/Co/Au, Zr/Al/Ti/Au, Zr/Al/Pt/Au, Zr/Al/Ni/Au, Zr/Al/Pd/Au, Zr/Al/Cr/Au, Zr/Al/Co/Au, TiNₓ/Ti/Au, TiNₓ/Pt/Au, TiNₓ/Ni/Au, TiNₓ/Pd/Au, TiNₓ/Cr/Au, TiNₓ/Co/Au TiWNₓ/Ti/Au, TiWNₓ/Pt/Au, TiWNₓ/Ni/Au, TiWNₓ/Pd/Au, TiWNₓ/Cr/Au, TiWNₓ/Co/Au, NiAl/Pt/Au, NiAl/Cr/Au, NiAl/Ni/Au, NiAl/Ti/Au, Ti/NiAl/Pt/Au, Ti/NiAl/Ti/Au, Ti/NiAl/Ni/Au, Ti/NiAl/Cr/Au or the like. The material of the second electrode 270 may comprise metallic alloys such as Ni/Au, Ni/Pt, Ni/Pd, Ni/Co, Pd/Au, Pt/Au, Ti/Au, Cr/Au, Sn/Au, Ta/Au, TiN, TiWNₓ, WSiₓ or the like.

Besides, the roughness layer may be formed on one or more of the films of the LED to further enhance the extraction efficiency of the LED, and the number and position of the roughness layers are not limited in the present invention. The LED devices having two or more roughness layers are illustrated in the following.

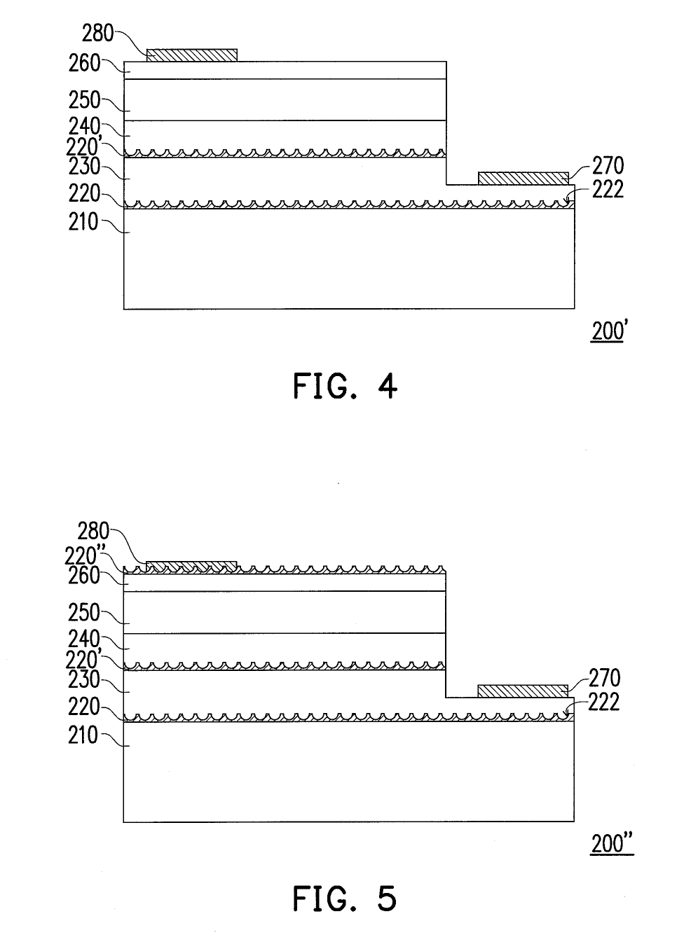

FIG. 4 is a cross-sectional view showing an LED having two roughness layers according to another preferred embodiment of the present invention. Please refer to FIG. 4, the structure of the LED 200′ is similar to that of the LED 200 shown in FIG. 3, and the difference between them lies in that the LED 200′ further comprises a second roughness layer 220′ disposed on the first type doped semiconductor layer 230. The structure and material of the second roughness layer 220′ are the same as those of the first roughness layer 220, and therefore it is not repeated herein.

FIG. 5 is a cross-sectional view showing an LED having three roughness layers according to another preferred embodiment of the present invention. Please refer to FIG. 5, the structure of the LED 200″ is similar to that of the LED 200′ shown in FIG. 4, and the difference between them lies in that the LED 200″ further comprises a third roughness layer 220″ disposed on the transparent conductive layer 260. The structure and material of the third roughness layer 220″ are the same as those of the first roughness layer 220, and therefore it is not repeated herein.

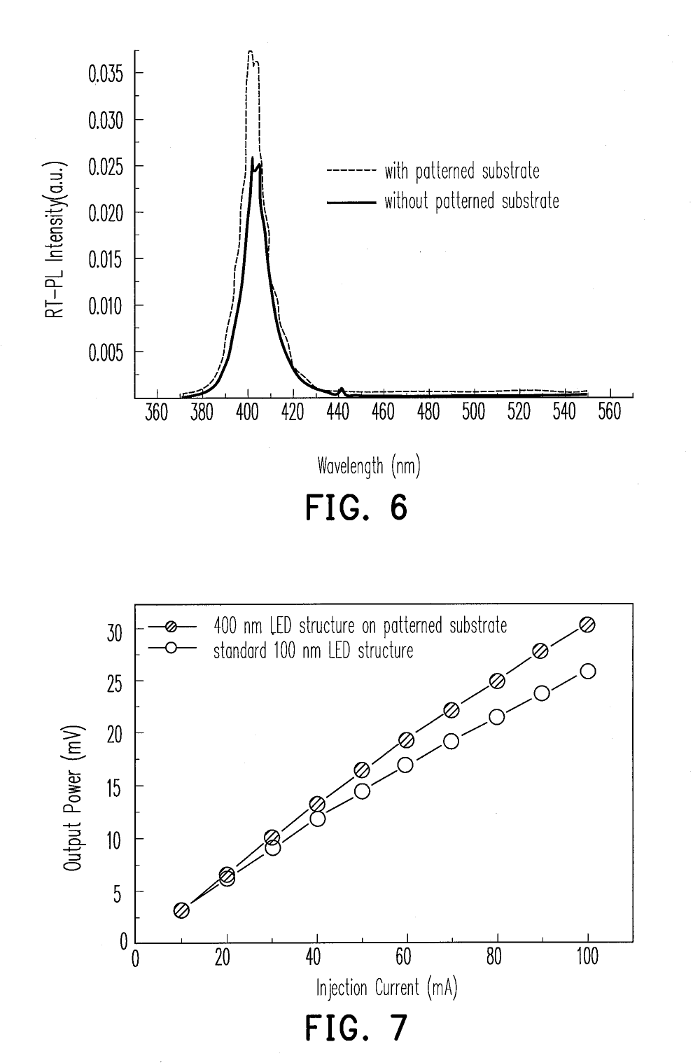

FIG. 6 is a diagram illustrating a relationship of wavelength and RT-PL intensity measured from the standard 400 nm LED structure and the 400 nm LED structure on the substrate having the nano/micro structure according to an embodiment of the present invention. FIG. 7 is a diagram illustrating a relationship of injection current and EL integrated intensity measured from the standard 400 nm LED structure and the 400 nm LED structure on the substrate having the nano/micro structure according to an embodiment of the present invention. It is clear from FIGS. 6 and 7, compared with the standard 400 nm LED structure, the RT-PL intensity and EL integrated intensity of the 400 nm LED structure on the substrate having the nano/micro structure are improved.

### Second Embodiment

The present embodiment is approximately identical to the first embodiment, and same or similar reference numbers used in the present embodiment and in the first embodiment represent the same or the like elements. Accordingly, no further description thereof is provided hereinafter. On the other hand, the difference between the present embodiment and the first embodiment will be demonstrated as follows.

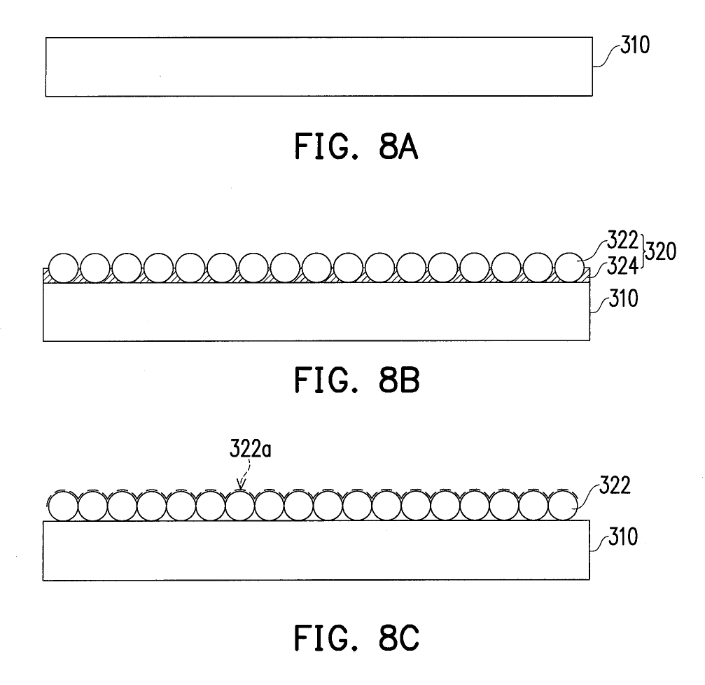

Referring to FIG. 8A, a substrate 310 is provided. Then, as shown in FIG. 8B, a plurality of ball-shape particles 322 is formed on the substrate 310, wherein the ball-shape particles 322 are mixed within a filler 324 to form a mixed material 320. Referring to FIG. 8C, placing the substrate 310 with the mixed material 320 thereon for a while, then the filler 324 is natural drying to vanish, and the ball-shape particles 322 are joined together and standing on the substrate 310. The ball-shape particles 322 are joined together and form a joined surface with a plurality of concaves 322a, which serve as a roughness surface. Afterward, forming layers such as doped semiconductor layers, a light emitting layer, a transparent conductive layer and electrodes on the substrate 310 in following steps not illustrated in this embodiment, so as to fabricate an LED. Therefore, the roughness surface formed on the substrate 310 can enhance the extraction efficiency of the LED. It should be noted that the roughness surface is not limited to be disposed on the substrate 310 only. In other embodiments, the roughness surface can also be disposed any two layers therebetween of the LED, or on the transparent conductive layer, according to actual requirements.

### Third Embodiment

The present embodiment is approximately identical to the first embodiment, and same or similar reference numbers used in the present embodiment and in the first embodiment represent the same or the like elements. Accordingly, no further description thereof is provided hereinafter. On the other hand, the difference between the present embodiment and the first embodiment will be demonstrated as follows.

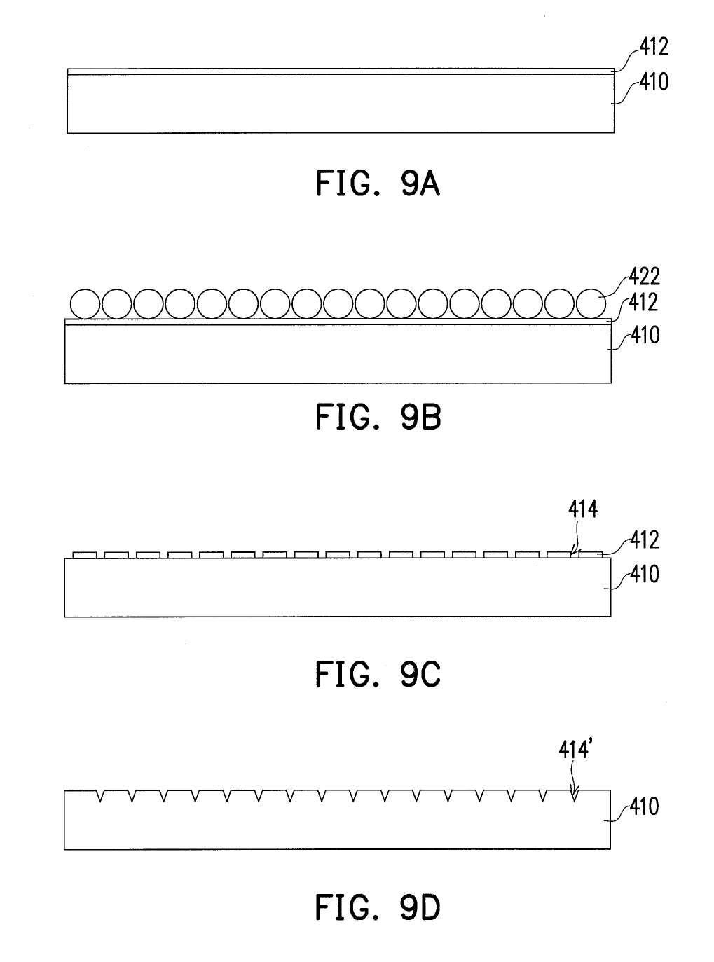

Referring to FIG. 9A, a substrate 410 is provided, and a monolayer 412 is formed on the substrate 410. The method of forming the monolayer 412 on the substrate is plasma-enhanced chemical vapour deposition.

Then, as shown in FIG. 9B, forming a plurality of ball-shape particles 422 on the monolayer 412. Later, referring to FIG. 9C, performing an etching procedure on the ball-shape particles 422 and the substrate 410 with the monolayer 412 thereon, and a plurality of concaves is formed.

In this embodiment, a material of the substrate 410 is Si, a material of the monolayer 412 is AlGaN, and the AlGaN monolayer 412 serves as a seed layer for growing a GaN layer thereon later. Here, the procedure performing on the ball-shape particles 422 and the substrate 410 is dry etching, and then the monolayer 412 is patterned. That is to say, portions of the monolayer 412 are still reserved on the substrate 410, and the concaves are on the surface of the monolayer 412 and extending into the substrate 410. After the etching procedure, growing the GaN layer on the substrate 410 with the patterned monolayer 412, and the structural and optical properties of the GaN films are assessed and shown to be better than those of the films grown on the substrate 410 without the seed monolayer 412. More particularity, the GaN layer formed on the monolayer 412 has lower residual stress and is crack-free and smooth.

In another embodiment, a material of the substrate 410 is sapphire, and a material of the monolayer 412 is SiO2. As shown in FIG. 9D, the step of performing an etching procedure on the ball-shape particles 422, the monolayer 412 and the substrate 410 further comprises etching until the monolayer 412 is completely removed from the substrate 410. Therefore, the concaves 414′ are formed on a surface of the substrate 410. The material of the monolayer 412 mentioned above are exemplary, and people skilled in the art can choose the material such as plastic, metal, metal-oxide or a combination thereof to form the monolayer in accordance with actual requirements.

### Fourth Embodiment

The present embodiment is approximately identical to the third embodiment, and same or similar reference numbers used in the present embodiment and in the third embodiment represent the same or the like elements.

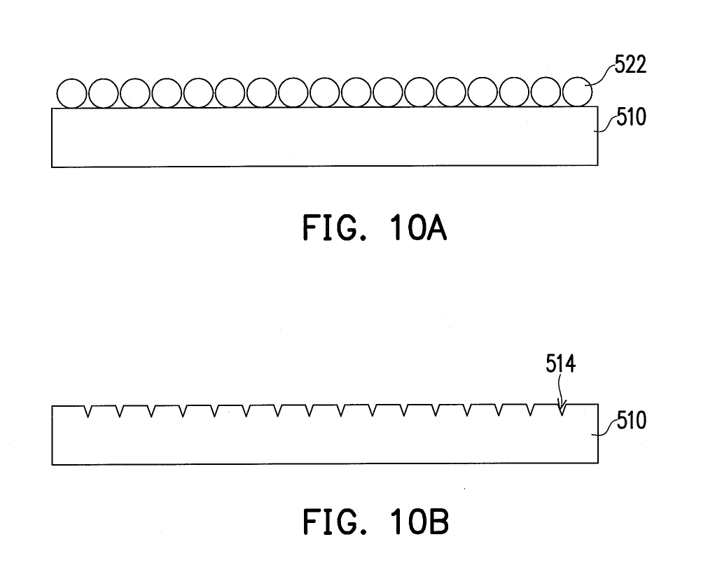

Referring FIGS. 10A and 10B, in this embodiment, the monolayer 412 (shown in FIG. 9B) is omitted, and the ball-shape particles 522 are formed on the substrate 510 directly. Then, perform an etching process to the ball-shape particles 522 and the substrate 510, and the ball-shape particles 522 are used as a mask, therefore a plurality of concaves are formed on a surface of the substrate 510.

In summary, the present invention is to form a mixed material comprising a plurality of ball-shape particles and the filler among the ball-shape particles on the film. Then, the ball-shape particles are removed by the etching process, the solvent extraction process or the thermal treatment process, such that the micro-scaled or nano-scaled concaves are formed on the surface of the filler, which serves as the nano/micro structure of the film. The fabrication of the nano/micro structure may be applied to one or more of the films of the LED device to be roughed, such that the extraction efficiency of the LED device may be enhanced. Compared with the etching process, the fabrication method of the present invention may reduce the fabrication time and cost effectively, thus increasing the productivity of the LED device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a nano/micro structure, comprising:
providing a substrate; and
forming a plurality of ball-shape particles on the substrate.

2. The method of fabricating a nano/micro structure according to claim 1, wherein the substrate is a film, a silicon substrate, a sapphire substrate, a plastic substrate, a metal substrate or a metal-oxide substrate.

3. The method of fabricating a nano/micro structure according to claim 1, wherein the ball-shape particles are mixed within a filler to form a mixed material.

4. The method of fabricating a nano/micro structure according to claim 3, wherein a material of the filler comprises an inorganic material.

5. The method of fabricating a nano/micro structure according to claim 4, wherein the inorganic material comprises metal alkoxides, metal oxide precursor or a plurality of metal particles.

6. The method of fabricating a nano/micro structure according to claim 3, after the step of forming the ball-shape particles on the substrate, further comprises a step of removing the ball-shape particles to form a plurality of concaves on a surface of the filler.

7. The method of fabricating a nano/micro structure according to claim 3, wherein the mixed material is formed on the substrate by spinning coating, dip coating or natural drying.

8. The method of fabricating a nano/micro structure according to claim 1, wherein a material of the ball-shape particles comprises polymer, metal or metal oxide.

9. The method of fabricating a nano/micro structure according to claim 1, wherein the ball-shape particles comprise a plurality of micro-scaled particles, a plurality of nano-scaled particles, or a mixture of the micro-scaled particles and the nano-scaled particles.

10. The method of fabricating a nano/micro structure according to claim 1, further comprises removing the ball-shape particles by an etching process, a solvent extraction process or a thermal treatment process.

11. The method of fabricating a nano/micro structure according to claim 1, before the step of forming the ball-shape particles on the substrate, further comprises a step of depositing at least one monolayer on the substrate.

12. The method of fabricating a nano/micro structure according to claim 11, wherein a material of the monolayer is plastic, metal, metal-oxide or a combination thereof.

13. The method of fabricating a nano/micro structure according to claim 11, after the step of forming the ball-shape particles on the substrate, further comprises a step of etching the ball-shape particles, the monolayer and the substrate by using the ball-shape particles as a mask to form a plurality of concaves on a surface of the substrate or the monolayer.

14. The method of fabricating a nano/micro structure according to claim 1, after the step of forming the ball-shape particles on the substrate, further comprises a step of etching the ball-shape particles and the substrate by using the ball-shape particles as a mask to form a plurality of concaves on a surface of the substrate.
